(19) United States
(12) Patent Application Publication
(10) Pub. No.: US 2014/0154629 A1
(43) Pub. Date: Jun. 5, 2014

(54) LITHOGRAPHY APPARATUS AND METHOD OF MANUFACTURING ARTICLE

(71) Applicant: CANON KABUSHIKI KAISHA, Tokyo (JP)

(72) Inventor: Hiromi Kinebuchi, Utsunomiya-shi (JP)

(73) Assignee: CANON KABUSHIKI KAISHA, Tokyo (JP)

(21) Appl. No.: 14/091,225

(22) Filed: Nov. 26, 2013

(30) Foreign Application Priority Data
Nov. 30, 2012 (JP) 2012-263513

(51) Int. Cl. H01J 37/317

(52) U.S. Cl. CPC H01J 37/3174
USPC 430/296; 250/492.3

(57) ABSTRACT

A lithography apparatus that performs drawing on a substrate with an energy beam based on bitmap data generated via an error diffusion from pattern data includes a smoothing device configured to perform smoothing on the pattern data before the error diffusion.

### BACKGROUND OF THE INVENTION

1. Field of the Invention

The present invention relates to a lithography apparatus that performs drawing on a substrate using an energy beam, and a method of manufacturing an article using the same.

2. Description of the Related Art

As a lithography apparatus used for manufacturing devices such as semiconductor integrated circuits, a drawing apparatus that performs drawing on a substrate using a plurality of charged particle beams is discussed (Japanese Patent Application Laid-Open No. 9-7538). In such a drawing apparatus, drawing can be performed by main-scanning with each charged particle beam and sub-scanning on the substrate.

Bitmap data supplied to the drawing apparatus has an enormous amount of data. For example, a drawing region with a size of 20 mm×20 mm is equivalent to 16 T (tera) (10¹²) pixels, when one pixel has a size of 5 nm×5 nm, and is equivalent to data amount of 16 T bytes, when a dose amount (exposure amount) of one pixel is expressed by one byte. From the viewpoint of throughput of the drawing apparatus, it is desirable to be able to transfer bitmap data in a short time to a device (for example, blanking device) that performs modulation of dose amount for each pixel. Consequently, a method for decreasing the number of gradations of the bitmap data, and reducing the data amount is employed.

However, it may be disadvantageous to obtain a line width (or uniformity of line width) of a targeted pattern, only by decreasing the number of gradations by simply performing change (round up or round down) of a pixel value, an excess or deficiency of the dose amount occurs. Thus, to decrease the number of gradations, it is advisable to use an error diffusion method. The error diffusion method is advantageous to reduce an error (excess or deficiency) of the dose amount that may be caused by the decrease in the number of gradations, since an error (quantization error) of a pixel value of each pixel associated with the decrease in the number of gradations is diffused among neighboring pixels.

However, a drawing pattern for a device such as a semiconductor integrated circuit finds a sharp change in a pixel value on a border portion between a drawing region and a non-drawing region. If an error is diffused beyond such the border portion, pixels among which an error is diffused find difficulty in compensating for the error. In other words, for example, if a quantization error of a pixel whose pixel value has been rounded up is diffused among neighboring pixels, there may occur a case where the pixel value is too small to completely compensate for the diffused error among the neighboring pixels. This is because, if an absolute value of diffused negative error is greater than an absolute value of the pixel value, a pixel value obtained by the error diffusion becomes negative, but the negative pixel value cannot be realized, and the pixel value is made zero in conjunction with drawing. In this case, a dose amount becomes excessive in a region containing these pixels, and it can occur that a line width of the targeted pattern cannot be obtained (for example, the line width becomes thick). Further, for example, in a case where a quantization error of a pixel whose pixel value has been rounding down is diffused among the neighboring pixels, it can occur that the pixel value is too great to completely compensate for the diffused error among the neighboring pixels. In this case, it can occur that the dose amount is deficient in a region containing these pixels, and the targeted line width of the pattern is not obtained (for example, the line width becomes thin).

### SUMMARY OF THE INVENTION

The present invention is directed to a lithography apparatus that is, for example, advantageous for reduction of change of a line width associated with an error diffusion.

According to an aspect of the present invention, a lithography apparatus that performs drawing on a substrate with an energy beam based on bitmap data generated via an error diffusion from pattern data includes a smoothing device configured to perform smoothing on the pattern data before the error diffusion.

Further features of the present invention will become apparent from the following description of exemplary embodiments with reference to the attached drawings.

### BRIEF DESCRIPTION OF THE DRAWINGS

FIG. 1 is a diagram illustrating a configuration example of a drawing apparatus according to a first exemplary embodiment.

FIG. 2 is a diagram illustrating an example of candidate bitmap data for error diffusion processing.

FIG. 3 is a flowchart illustrating an example of flow of data processing concerning a comparative example.

FIGS. 4A, 4B, 4C, and 4D are diagrams for explaining error diffusion concerning comparative examples.

FIG. 5 is a flowchart illustrating an example of flow of data processing according to the first exemplary embodiment.

FIGS. 6A, 6B, and 6C are diagrams for explaining error diffusions according to the first exemplary embodiment.

FIGS. 7A and 7B are diagrams illustrating results of simulations of line width errors.

FIGS. 8A, 8B, 8C, and 8D are diagrams illustrating configuration examples of a low-pass filter.

FIG. 9 is a flowchart illustrating an example of flow of data processing according to a second exemplary embodiment.

FIG. 10 is a diagram illustrating a configuration example of a drawing apparatus according to the second exemplary embodiment.

### DESCRIPTION OF THE EMBODIMENTS

Various exemplary embodiments, features, and aspects of the invention will be described in detail below with reference to the drawings.

The same reference numerals are assigned to the same members or the like, and repetitive descriptions thereof will be omitted, throughout the drawings for illustrating exemplary embodiments, as a general rule.

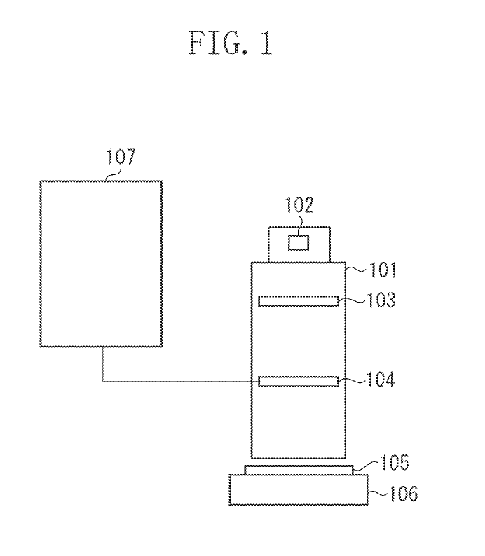

FIG. 1 is a diagram illustrating a configuration example of a drawing apparatus as a lithography apparatus according to a first exemplary embodiment. The drawing apparatus performs drawing on a substrate (for example, silicon wafer) 105 coated with resist thereon via a charged particle lens barrel 101 (also simply referred to as a lens barrel or a column) with a charged particle beam (for example, electron beam). The charged particle lens barrel 101 includes a charged particle source 102 that emits a charged particle, a charged particle optical system 103 that projects the charged particle beam onto the substrate while shaping and scanning the beam, and a blanking device 104 that performs blanking of the charged particle beam. The drawing apparatus includes a control unit 107 that controls the blanking device 104. The control unit 107 transmits control data for blanking to the blanking device 104. The control unit 107 generates binarized bitmap from vector data or gray level data (gray level bitmap) corresponding to the pattern which is to be drawn, in order to generate the control data. A substrate stage 106 (also simply referred to as a stage) that is movable and holds the substrate 105. The drawing apparatus performs drawing on the substrate 105, by synchronizing main-scanning of the charged particle beam by the charged particle optical system 103, blanking by the blanking device 104, and sub-scanning on the substrate 105 by the substrate stage 106.

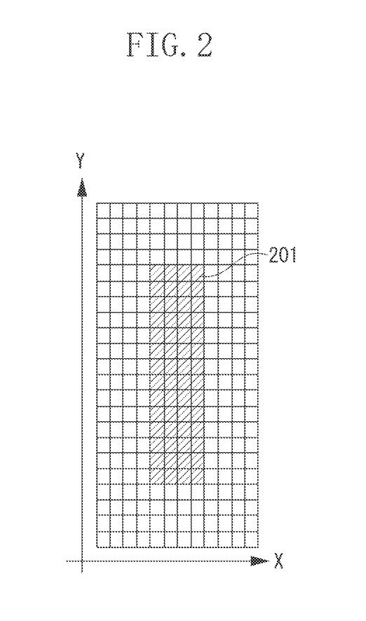

The drawing apparatus controls the blanking device 104, based on the above-described gray level data. The control unit 107 converts, if vector data is input, the vector data into gray level data in accordance with a pixel array defined in the drawing apparatus. The gray level data is bitmap, and coordinates of respective pixels correspond to positions at which the charged particle beams are irradiated, and values of respective pixels correspond to dose amounts of the charged particle beams (intensities or irradiation times of the charged particle beams). In FIG. 2, an example of the gray level bitmap is illustrated. A hatching portion 201 corresponds to a pattern which is to be drawn, and the pattern is a straight line or a rectangular pattern with a width of four pixels. An interval (pitch) of the pixels can be determined by, for example, a main-scanning speed of the charged particle beam by the charged particle optical system 103 and a control cycle of the blanking device 104. For example, in FIG. 2, if a pixel interval is 5 nm, a width of the straight line pattern becomes 20 nm.

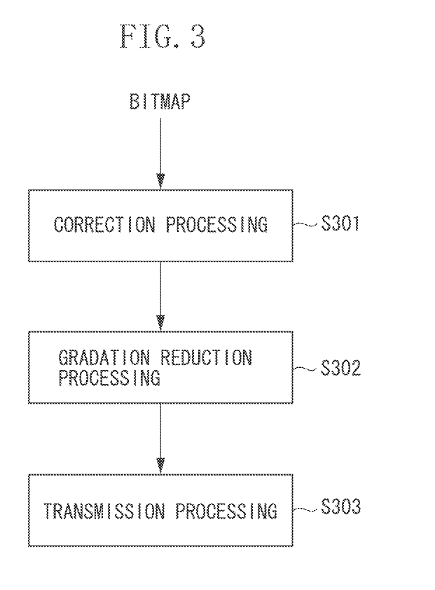

FIG. 3 is a flowchart illustrating an example of the flow of data processing concerning a comparative example. Pattern data to be input can be set to the above-described gray level bitmap created by converting design data (vector data) of a device pattern such as a computer-aided design (CAD) file. In step S301, the bitmap data is subjected to necessary correction processing. The correction processing includes the one related to a recipe (e.g., a pattern which is to be drawn or a substrate to be drawn) such as geometrical conversion based on proximity effect correction or alignment measurement results, and the one related to characteristics of apparatus such as an array of the charged particle beam or compensation for the deviation from a nominal (value) of characteristics. In step S302, the pattern data which has been subjected to the correction processing will be subjected to gradation reduction processing (quantization processing for reducing the number of gradation levels, for example, binarization processing). In this case, error diffusion processing is employed for the gradation reduction processing. In step S303, the pattern data which has been subjected to the gradation reduction, is directly, or after further being processed, transmitted to the blanking device, as control data. The blanking device performs blanking of the charged particle beam based on the control data.

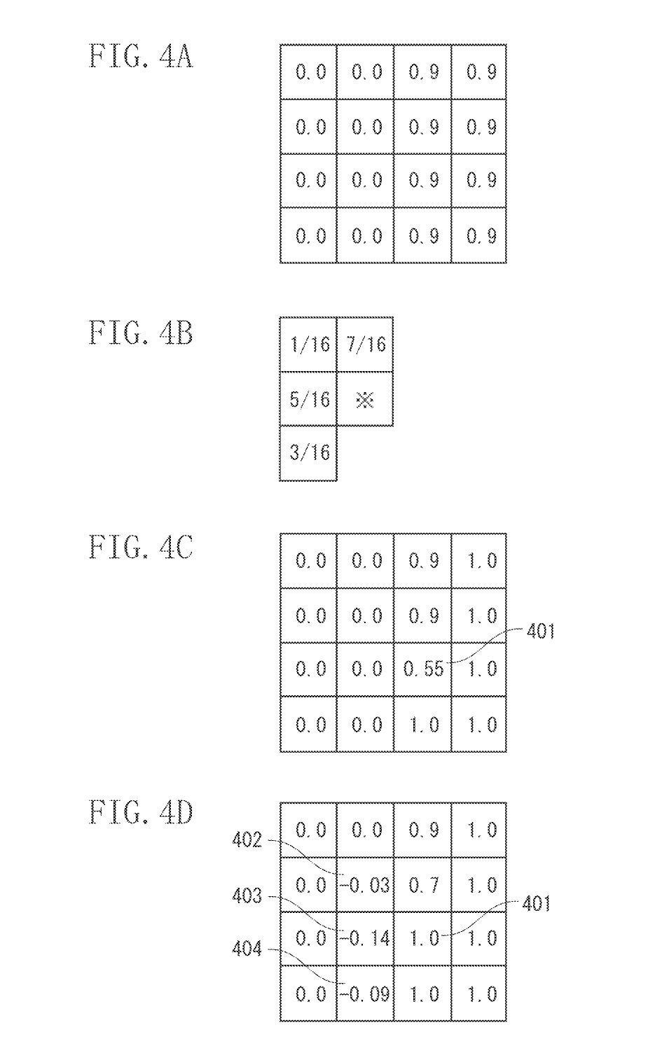

Even when the error diffusion processing is employed for the gradation reduction processing in step S302, the dose amount (exposure amount) may be excessively changed, as described above. Referring to FIGS. 4A, 4B, 4C, and 4D, their concrete examples will be described. FIGS. 4A, 4B, 4C, and 4D are diagrams for explaining the error diffusions concerning comparative examples. FIG. 4A is a portion of gray level bitmap, and is focused on the neighborhood of the border of patterns. The pixel having a value of 0.9 is a pixel in a region where a pattern exists, and the pixel having a value of 0 is a pixel in a region where a pattern does not exist. This bitmap is converted into bitmap with 2 gradations (binary). A value zone of the pixel value is between 0 and 1, and a threshold value for the gradation reduction is set to an intermediate value of 0.5. The gradation reduction (error diffusion) starts with a lower right pixel, and the processing proceeds upward one by one pixel. After finishing the processing for one vertical column, similar processing is performed from a pixel located at the lowest of an immediate left column. Since then, the processing is similarly repeated for the remaining columns. A weight matrix used for the error diffusion is illustrated in FIG. 4B. An error of the pixel value associated with the gradation reduction (quantization) is distributed (diffused) among peripheral pixels in accordance with the weight matrix.

FIG. 4C illustrates a state where gradation reduction processing has progressed halfway. A pixel 401 is a pixel targeted for the next gradation reduction processing, and its pixel value is 0.55. The original value was 0.9, but the value is changed by an error diffused from the pixel subjected to the gradation reduction previously. Since the pixel value is greater than the preset threshold value of 0.5, it is converted into 1. Therefore, an error which should be diffused is 0.55−1.0=−0.45. The error is diffused among peripheral pixels in accordance with a weight matrix illustrated in FIG. 4B. FIG. 4D illustrates a state where the error has been diffused. Pixels 402, 403, and 404, whose original values each were 0, now take negative values.

Furthermore, when the gradation reduction processing is performed on the pixel 404, since a pixel value of −0.09 is smaller than the threshold value of 0.5, it is converted into 0. Therefore, an error which should be diffused is −0.09−0=−0.09. In other words, the error generated at the pixel 401 cannot be compensated at the pixel 404 and is further diffused among the peripheral pixels, and a similar operation will be repeated even at diffusion destination pixels each having the pixel value of 0. An error generated at a certain pixel should be inherently compensated by neighboring pixels of the pixel. If negative error would be diffused among distant (faraway) pixels like the examples in FIGS. 4A, 4B, 4C, and 4D, a dose amount of a region containing the pixel which has generated an error will be larger than the inherent amount (ideal value). Such an excess of the dose amount results in breaking the shape of a resist pattern after development (for example, a line width is made thick). Further, in contrast, if a quantization error of the pixel whose pixel value has been rounded down, is diffused among the neighboring pixels, there may occur a case where the pixel value is too great to completely compensate for the diffused error among the neighboring pixels. In this case, a dose amount in a region containing these pixels becomes deficient, and it may result in damaging a shape of the resist pattern (for example, the line width is made thin).

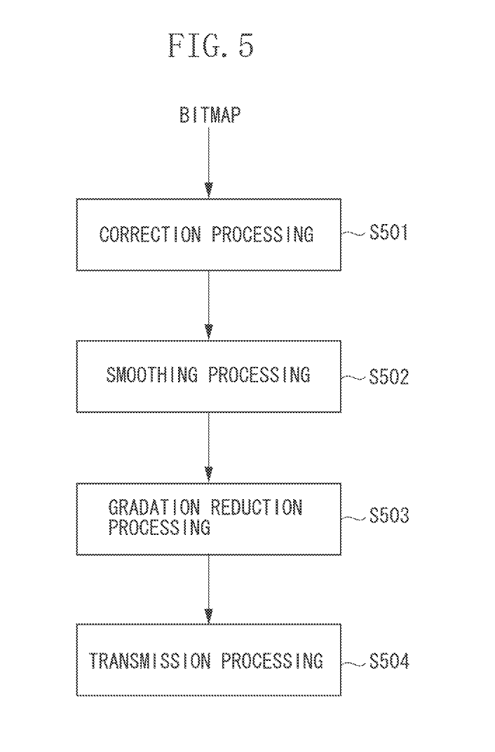

FIG. 5 is a flowchart illustrating an example of the flow of the data processing according to the present exemplary embodiment. Difference from the data processing concerning the above-described comparative example (in FIG. 3) is that the smoothing processing (in step S502) is added, before the gradation reduction processing (in step S503). The contents of the processing in steps S501, S503, and S504 may be similar to the case of the comparative example (in FIG. 3).

The smoothing processing (in step S502) is processing for smoothing gray level bitmap data subjected to the correction processing (in step S501) by the low-pass filter. By the processing, change of pixel values on the border portion of the pattern becomes moderate, and, therefore, it becomes advantageous to compensate for errors to be diffused. That is, the errors that cannot be completely compensated becomes able to be reduced.

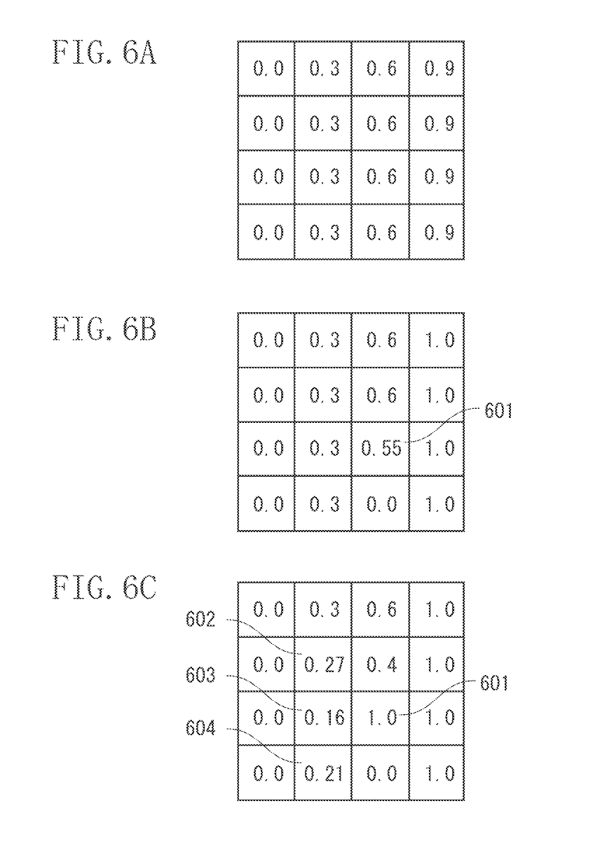

FIGS. 6A, 6B, and 6C are diagrams for explaining the error diffusion according to the present exemplary embodiment, and illustrate a state of the error diffusion with respect to gray level bitmap subjected to the smoothing processing. FIG. 6A illustrates a part of gray level bitmap smoothed via the low-pass filter, and near the border of a pattern. The gradation reduction processing similar to the cases in FIGS. 4A, 4B, 4C, and 4D is supposed to be performed on this bitmap. FIG. 6B is a state where the gradation reduction has progressed halfway, and a pixel 601 is a pixel targeted for the next gradation reduction processing. Since a pixel value of 0.55 of the pixel 601 is greater than the threshold value 0.5, it is converted into a pixel value of 1.0. The error in this case is 0.55−1.0=−0.45. FIG. 6C is a result of having caused the error generated at the pixel 601 to be diffused according to the weight matrix (see FIG. 4B). As a result that change in the pixel values on the border portion in the bitmap data has become moderate by the smoothing processing, a margin of the pixel values enough to enable compensation for an error generated by binarization (quantization) is assigned to the pixels on the border portion, and negative pixel values have become less generated in the course of the error diffusion processing.

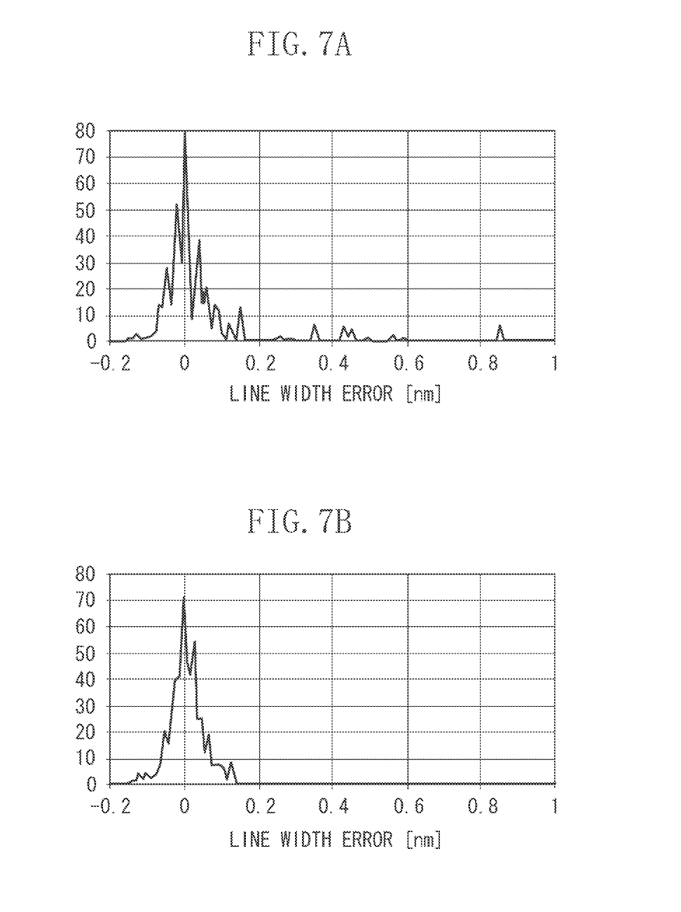

FIGS. 7A and 7B are diagrams illustrating results of simulations of line width errors. The simulation includes preparing 500 types of gray level bitmaps containing isolated various line patterns, and performing data processing on each type to obtain a line width.

In FIGS. 7A and 7B, the horizontal axis of the graph represents errors of the obtained line widths relative to a target line width, and the vertical axis represents the number (frequency) of patterns having errors. FIG. 7A illustrates a result of having performed data processing concerning the above-described comparative example. Patterns whose line width errors have ended up becoming positive (i.e., thicker than the target line width), appear even on the line width errors away far from a mean value (or a line width error of 0) of the line width errors. FIG. 7B illustrates a result of having performed data processing according to the present exemplary embodiment. The patterns which have generated great line width errors as can be seen in FIG. 7A disappear (or are reduced). In the configuration illustrated in FIG. 5, the smoothing processing is performed immediately before the gradation reduction processing, but it is not limited to this, and the smoothing processing may be performed on an appropriate stage before the gradation reduction processing, such as before or in the course of the correction processing (in step S501).

In the smoothing processing, the low-pass filter, as is the one typically used for natural images, may isotropically utilize peripheral pixel values of a processing target pixel (also simply referred to as a target pixel). However, in a characteristic pattern like a pattern for semiconductor integrated circuits, peripheral pixels may be selectively utilized in the low-pass filter. The pattern for semiconductor integrated circuits, typically, is based on line segments and rectangles that run (extend) horizontally and vertically. Consequently, the low-pass filter for feathering a border of the pattern, selectively utilize at least one of pixels adjacent to the processing target pixel in the vertical direction and pixels adjacent to the processing target pixel in the horizontal direction, and a coefficient matrix corresponding to this may be utilized. By thus utilizing values of some pixels out of the peripheral pixels for the smoothing operation, load or time involved in calculations can be reduced.

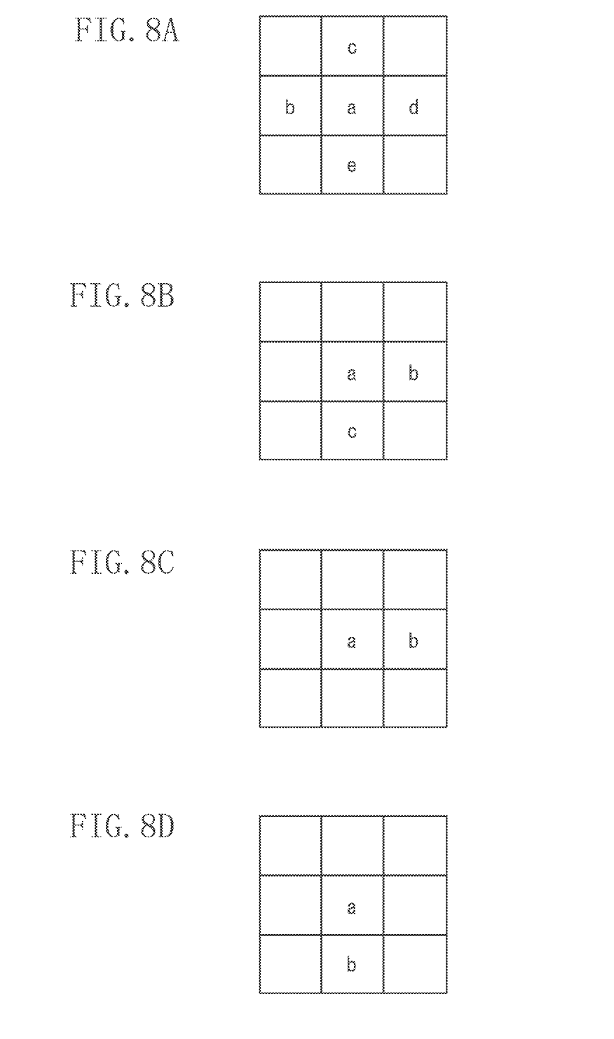

FIGS. 8A, 8B, 8C, and 8D are diagrams illustrating configuration examples of the low-pass filter. FIG. 8A illustrates an example of coefficient matrix used for the low-pass filter. The matrix utilizes pixel values of two pixels adjacent to the processing target pixel in the vertical direction and two pixels (four pixels in total) adjacent to the processing target pixel in the horizontal direction, and does not utilize pixel values of four pixels adjacent to the processing target pixel in an oblique direction. FIG. 8B is an example of another coefficient matrix. This is an example of utilizing values of two pixels which do not diffuse quantization error of the processing target pixel, out of four pixels adjacent to the processing target pixel in the vertical direction or horizontal direction. In the present exemplary embodiment, gradation reduction (error diffusion), starting with a lower right pixel and the processing is progressed one by one pixel upward, and even immediate left columns are supposed to be repeated in sequence. Consequently, errors which are not diffused, out of four pixels adjacent to the processing target pixel in the vertical direction or horizontal direction are two pixels of right-side and lower-side of the processing target pixel.

A phenomenon of the inability to compensate for a diffused error may differently appear depending on attributes of pixels involved in the error diffusion. The phenomenon, as described above, may occur markedly when an error is diffused from a pixel in the interior of the pattern to pixels in the exterior of the pattern. For example, if the gradation reduction is being progressed from a lower-right pixel as described above, the above-described phenomenon is likely to appear on a left-side border and an upper-side border of a straight line or rectangular pattern 201. In contrast, since an error is diffused in the interior of the pattern, on a right-side border and a lower-side border of the straight line or rectangular pattern 201, the above-described phenomenon is difficult to appear. Therefore, in this case, pixels to be smoothed may suffice for at least some pixels located along the left-side border and the upper-side border of the pattern. In this case, which adjacent pixels are utilized for the smoothing operation may be changed depending on directions in which the error diffusion processing sequentially progresses. Unlike the descriptions so far, if the error diffusion processing is to be progressed starting with the upper-left pixel, then pixels to be utilized for the smoothing operation may be two pixels of the left-side and the upper-side of the processing target pixel to which the error is not diffused, out of four pixels adjacent to the processing target pixel in the vertical direction and horizontal direction.

FIGS. 8C and 8D illustrate examples of further separate coefficient matrixes. FIG. 8C illustrates an example where values of pixels located at the right-side out of four pixels adjacent to the processing target pixel are selectively utilized for the smoothing operation. FIG. 8D illustrates an example where values of pixels located at the lower-side out of four pixels adjacent to the processing target pixel are selectively utilized for the smoothing operation. A coefficient matrix for the smoothing processing may be the one usable for obtaining a mean value of the values of all pixels to be utilized for the smoothing operation, or may be the one usable for assigning non-uniform weights to the values of all pixels to be utilized for the smoothing operation.

As described above, according to the present exemplary embodiment, a drawing apparatus having an advantage of reducing change (excessive change of dose amount) of line width involved in the error diffusion can be provided. In other words, for example, in a case where quantization error of a pixel whose pixel value has been rounded up is diffused among neighboring pixels, it may reduce the occurrence of an event where the pixel value is too small to completely compensate for the diffused error among the neighboring pixels, and thus a dose amount is excessive in a region containing these pixels. Further, for example, in a case where quantization error of a pixel whose pixel value has been rounded down is diffused among the neighboring pixels, it may reduce the occurrence of an event where the pixel value is too great to completely compensate for the diffused error among the neighboring pixels, and thus a dose amount is insufficient in a region containing these pixels.

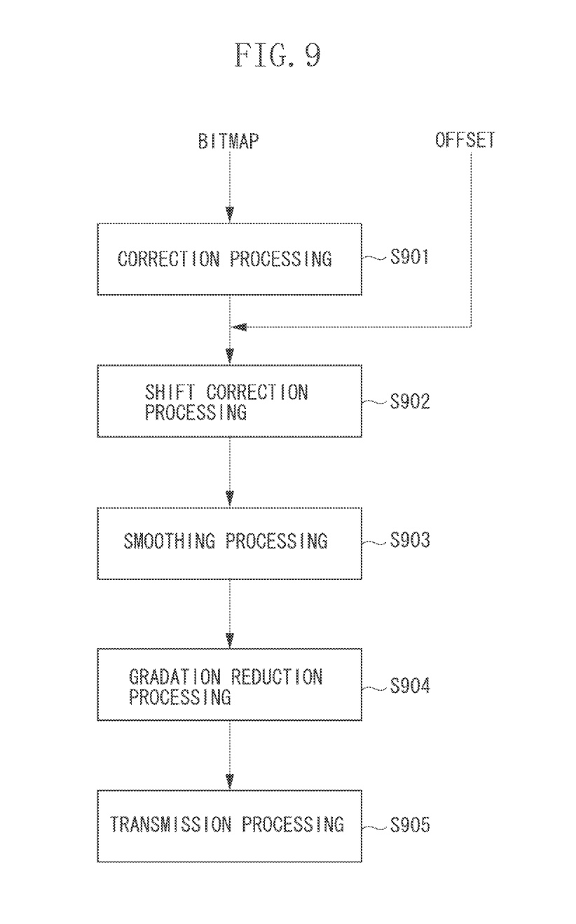

FIG. 9 is a flowchart illustrating an example of the flow of data processing according to a second exemplary embodiment.

If a coefficient matrix of the low-pass filter for use with smoothing is isotropic, there is no change of a position of a center of gravity between a pre-smoothing pattern and a post-smoothing pattern. However, if a coefficient matrix is anisotropic, the position of the center of gravity of a pattern will be changed depending on the coefficient matrix, via the smoothing processing. In this case, it follows that the position of the pattern drawn on a substrate by the drawing apparatus will be changed depending on the coefficient matrix.

Thus, in the present exemplary embodiment, movement processing for moving a pattern so as to compensate for movement of the center of gravity of a pattern caused by the smoothing processing is added. The movement processing constitutes a compensation unit in the drawing apparatus, and can be performed by utilizing geometrical conversion (for example, affine conversion) with respect to the bitmap data. In which direction and by what amount the center of gravity of a pattern moves only need to be obtained in advance based on the coefficient matrix to be used for the smoothing operation.

In the flow of data processing illustrated in FIG. 9, a difference from that in FIG. 5 is an addition of the above-described movement processing (in step S902). Processing in step S901 and steps S903 to S905 can be made similar to the processing in steps S501 to S504 in FIG. 5, respectively. The movement processing (in step S902) does not apply only to the case performed immediately before the smoothing processing, but can be performed on an appropriate stage before or after the smoothing processing.

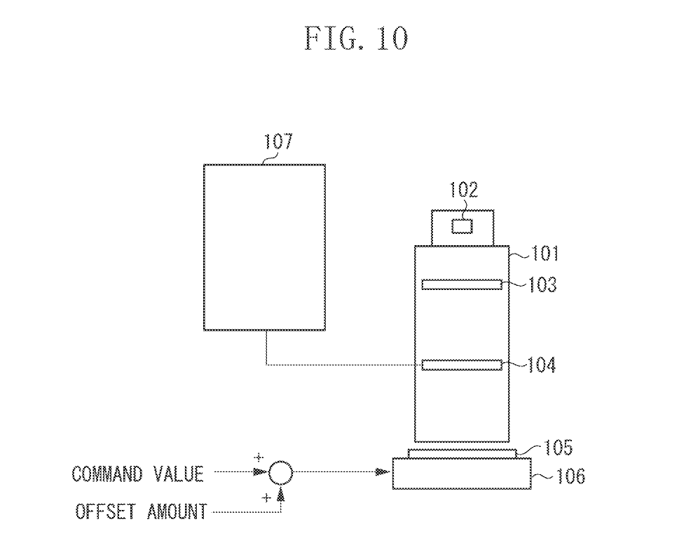

FIG. 10 is a diagram illustrating a configuration example of the drawing apparatus according to the present exemplary embodiment. The above-described movement of the center of gravity of the pattern can be also compensated by positioning of a substrate stage. In this case, the movement processing in step S902 constitutes a compensation unit in the drawing apparatus, and can be rendered as processing for setting an offset amount of the target position in the positioning so as to compensate for a movement amount of the center of gravity. In a configuration example of the drawing apparatus illustrated in FIG. 10, a difference from the configuration example in FIG. 1 is the ability to add the above-described offset amount to a command value (target position) to the substrate stage 106. Through such the configuration, in a case where a movement of the pattern is caused by the smoothing operation, positioning of the substrate stage can be performed to compensate for the movement.

A method of manufacturing an article according to an exemplary embodiments of the present invention is suitable for manufacturing various articles including, for example, microdevices such as semiconductor devices or elements each having microstructure. This manufacturing method can include a step of forming a (latent image) pattern on a substrate, coated with a photosensitizing agent, using the above-described lithography apparatus (drawing apparatus) (a step for performing drawing on a substrate), and a step of developing the substrate having the pattern formed thereon in the forming step. Furthermore, the manufacturing method can also include other known steps (for example, oxidation, film formation, vapor deposition, doping, planarization, etching, resist removal, dicing, bonding, and packaging). The method of manufacturing an article according to the present exemplary embodiment is advantageous in at least one of performance/quality/productivity/production cost of the article, as compared with the conventional method.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

In the above-described exemplary embodiments, a drawing apparatus that performs drawing on a substrate with the charged particle beam, has been illustrated as an example of the lithography apparatus, but an energy beam to be used for drawing is not limited to the charged particle beam, and other energy beams (for example, electromagnetic wave beams with various wavelengths) may be used. For example, a light beam such as ultraviolet ray can be used as other energy beam. In that case, the drawing apparatus may be configured to include a light source (for example, laser light source) in substitution for the charged particle generation source, and an optical system for projecting a light beam on the substrate while shaping and scanning the light beam in substitution for the charged particle optical system. Further, the blanking device may be configured to include a deflection device for deflecting the light beam for blanking purpose (for example, a digital mirror device).

This application claims the benefit of Japanese Patent Application No. 2012-263513 filed Nov. 30, 2012, which is hereby incorporated by reference herein in its entirety.

What is claimed is:

1. A lithography apparatus that performs drawing on a substrate with an energy beam based on bitmap data generated via error diffusion from pattern data, the lithography apparatus comprising:
a smoothing device configured to perform smoothing on the pattern data before the error diffusion.

2. The lithography apparatus according to claim 1, wherein the smoothing device is configured to obtain, based on a value of a target pixel and at least one of a value of a pixel adjacent to the target pixel in a vertical direction and a value of a pixel adjacent to the target pixel in a horizontal direction, a value of the target pixel after the smoothing.

3. The lithography apparatus according to claim 1, wherein the smoothing device is configured to obtain, based on a value of a pixel to which a quantization error of a target pixel is not diffused by the error diffusion out of pixels adjacent to a target pixel and a value of the target pixel, a value of the target pixel after the smoothing.

4. The lithography apparatus according to claim 3, wherein the smoothing device is configured to obtain, based on a value of one pixel to which a quantization error of a target pixel is not diffused by the error diffusion out of pixels adjacent to a target pixel and a value of the target pixel, a value of the target pixel after the smoothing.

5. The lithography apparatus according to claim 1, further comprising a compensation device configured to compensate for movement of pattern caused by the smoothing in the pattern data.

6. The lithography apparatus according to claim 5, wherein the compensation device is configured to perform a geometrical conversion on the pattern data.

7. The lithography apparatus according to claim 5, further comprising a stage configured to hold the substrate and to be movable,
wherein the compensation device is configured to set an offset amount for a target position in positioning of the stage, so as to compensate for the movement.

8. The lithography apparatus according to claim 1, wherein the lithography apparatus performs drawing on the substrate with a charged particle beam as the energy beam.

9. The lithography apparatus according to claim 8, further comprising a blanking device configured to operate based on the bitmap data.

10. The lithography apparatus according to claim 1, wherein the smoothing device is configured to obtain, based only on a value of a target pixel and at least one of a value of a pixel adjacent to the target pixel in a vertical direction and a value of a pixel adjacent to the target pixel in a horizontal direction, a value of the target pixel after the smoothing.

11. The lithography apparatus according to claim 1, wherein the smoothing device is configured to obtain, based only on a value of a pixel to which a quantization error of a target pixel is not diffused by the error diffusion out of pixels adjacent to the target pixel and a value of the target pixel, a value of the target pixel after the smoothing.

12. The lithography apparatus according to claim 3, wherein the smoothing device is configured to obtain, based only on a value of one pixel to which a quantization error of a target pixel is not diffused by the error diffusion out of pixels adjacent to the target pixel and a value of the target pixel, a value of the target pixel after the smoothing.

13. A method of manufacturing an article, the method comprising:
forming a pattern on a substrate using a lithography apparatus; and
developing the substrate, on which the pattern has been formed, to manufacturing the article,
wherein the lithography apparatus performs drawing on the substrate with an energy beam based on bitmap data generated via error diffusion from pattern data, the lithography apparatus including:
a smoothing device configured to perform smoothing on the pattern data before the error diffusion.
